(19) United States
(12) Patent Application Publication
(10) Pub. No.: US 2025/0379065 A1
(43) Pub. Date: Dec. 11, 2025

(54) METHOD FOR FABRICATING A FRAME OF A POWER MODULE, FRAME, AND POWER MODULE

(71) Applicant: Semikron Danfoss GmbH, Flensburg (DE)

(72) Inventors: Fabio Carastro, Munich (DE); Thomas Zoels, Herbertshausen (DE)

(21) Appl. No.: 19/230,399

(22) Filed: Jun. 6, 2025

(30) Foreign Application Priority Data
Jun. 10, 2024 (DE) 102024116175.2

(51) Int. Cl. H01L 21/48; H01L 21/66

(52) U.S. Cl. CPC H01L 21/481; H01L 22/14

(57) ABSTRACT

The disclosure relates to a method of forming a power module, wherein a current sensor is at least partially integrated in a mold of a frame of the power module. The disclosure relates further to a corresponding power module.

### CROSS-REFERENCE TO RELATED APPLICATION

This application claims foreign priority benefits under 35 U.S.C. § 119 to German Patent Application No. 102024116175.2 filed on Jun. 10, 2024, the content of which is hereby incorporated by reference in its entirety.

### TECHNICAL FIELD

The application relates to a method for fabricating a frame of a power module and to a corresponding frame and a corresponding power module.

### BACKGROUND

Power modules are used for various purposes when it comes to switching of currents, especially to switching of high currents. In certain applications, such currents should not only be switched, but should also be measured. Power modules often comprise frames that form a basis in which other components of the power module are placed.

### SUMMARY

It is thus an object of the present invention to provide a method for fabricating a frame of a power module that is optimized with regard to known methods for fabricating such a power module. It is a further object of the present invention to provide for a corresponding frame and a corresponding power module.

This is achieved by a method and by a frame and a power module according to the respective main claims. Preferred embodiments can, for example, be derived from the respective dependent claims.

The invention relates to a method for fabricating a frame of a power module, the method comprising the following steps:
providing a molding tool,
arranging components, namely at least a portion of a current terminal, at least a first core part of a core of a current sensor, and/or a portion of one or more connecting pins of the current sensor in the molding tool, and
forming the frame using the molding tool by injection-molding around the components arranged in the molding tool so that the components are embedded in the frame.

With such a method, a frame of a power module can be provided in a specifically easy way. Especially, the steps mentioned above may form a frame of a power module. The molding tool can provide for a certain structure of the frame to be formed, and can hold the components to be arranged inside the frame. The frame can form a substantial portion of the power module. For example, a semiconductor power switching circuit can be added to the frame in order to form a power module.

The frame can especially provide for a basis for other components. The injection-molding can especially be performed by applying a mold in a liquid state, which is then hardened. This forms a material of the frame.

The molding tool can be filled with a mold material. This mold material can then be hardened. After hardening, the material will typically constitute the frame. The material of the frame can surround the components mentioned above. Portions of these components can protrude from the material of the frame, e.g. portions of connecting pins and the current terminal, in order to allow an electrical connection with other entities. The first core part is typically surrounded completely by the material of the frame.

The current terminal can especially be embodied as a bulk structure being enabled for conducting a certain amount of current. It can, for example, have a rectangular cross-section. Especially, the current terminal may be a conductor through which a current to be measured flows. The first core part is typically embodied to form a core together with a second core part. Such a core is typically used in order to confine a magnetic field generated by current flowing through the current terminal. In final state, the first core part and the second core part may be arranged mirror-symmetrically to each other. The magnetic field can then be measured in order to get an indication of the current flowing. For this purpose, a magnetic sensor like a Hall element or another magnetic field sensing element can be used. Such a sensor may be placed in a gap between the assembled core parts.

The current terminal can be fully injection-molded especially along a portion of its lateral extension, or it can be injection-molded to such an extent that only a portion of it is covered by the material of the frame and a portion of it protrudes from the material. Typically, it at least protrudes from the material along a portion of its lateral extension to allow connection with other entities, especially with entities through with the current should also flow.

The connecting pins can especially be used in order to connect an electronic component, especially an electronic component of the current sensor such as a circuit board, to other components, especially to components being outside of the power module.

Especially, all components to be injection-molded around can be placed inside the molding tool. The molding tool may form a hollow space for containing these components. The molding tool may comprise a first part and a second part, especially being detachably fixed to each other and defining a hollow space between them in which a mold material is to be entered for injection-molding. A material of the frame is typically formed out of the mold material by hardening the mold material.

Especially, the frame may be formed to comprise a reception compartment for a semiconductor switching circuit. In such a reception compartment, one or more semiconductor switching circuits can be arranged and secured. The reception compartment can, for example, be delineated and/or closed by a detachable cover. There can also be more than one such reception compartments.

According to an implementation, the method may, after the step of injection-molding, further comprise the following step:
placing a circuit board of the current sensor and/or a second core part of the current sensor above the first core part outside a material forming the frame.

This can especially mean that the circuit board of the current sensor and/or the second core part are not yet present when performing the already mentioned step of injection-molding.

The circuit board of the current sensor can especially comprise components for measuring a magnetic field confined by the magnetic core and/or for evaluating such measurements. The circuit board and/or the current sensor may especially be positioned above the mold produced by the step of injection-molding.

The connecting pins may especially be double-headed pins each having a first connecting region facing upwards and a second connecting region facing upwards. This allows for connecting the circuit board from its lower side and to also connect other components from the side above the circuit board. Especially, all connecting regions may at least partially protrude from the material of the frame after the step of injection-molding. This allows placement and connection of the circuit board with at least some of the connecting regions.

It should be noted that mentioned positional relationships like “upward”, “lower”, or “above” relate to a typical orientation of the molding tool, the power module, the frame, or its components, but do not limit the scope of protection. For example, they may relate to an orientation in which a molding process or other fabrication processes are performed. However, the power module can also be used in other orientations.

Especially, the circuit board of the current sensor may be fixed on the first connecting regions. Thus, the first connecting regions both provide for holding the circuit board in place and for connecting the circuit board electrically.

The frame may especially be formed with a cavity in which the circuit board and the second core part are to be placed. Such a cavity may especially be open to the top and can be surrounded at other sides. This can provide for a free space in which the first connecting regions may protrude. The cavity may especially be defined as a region in the frame that is not filled to the top during the step of injection-molding. It may be defined by walls to other regions of the frame. Its structure may be given by a suitable design of a molding tool being used.

One or more connecting regions, especially first connecting regions, of the connecting pins may especially protrude in the cavity after forming the frame. Thus, the circuit board of the current sensor can also be arranged in the cavity and can be held in place by mechanical connection with the connecting regions.

Thus, the cavity can be used to form a reception room for these components. This can simplify positioning and securing these components.

The cavity may be filled with a non-conducting material, or an epoxy material, especially after the step of placing a circuit board of the current sensor and/or a second core part of the current sensor above the first core part. Thus, the cavity can be filled, covered components can be protected and it can be prevented that water or dust accumulates in the cavity.

The cavity can thus especially be formed while the step of injection-molding forming the frame. Then, further components like the circuit board and the second core part can be arranged in the cavity. The cavity can then be filled. Components placed in the cavity and the filling material then also form a portion of the frame.

Especially, the connecting pins may have a U-shape. This may especially mean that the first and second connecting regions may be arranged parallel to each other and/or may extend from a common connecting element or base portion in the same direction. One connecting region may be connected to the circuit board, the other connecting region may be connected to an external entity, for example in order to read out the current sensor. The connecting pins may be held in place in the molding tool by corresponding action of a protrusion of the connecting pin with a recess of the molding tool, or vice versa.

The first connecting regions and/or the second connecting regions may especially protrude outwards from the frame, or from a material of the frame, after injection-molding. This mold can be formed during the step of injection-molding. The first connecting regions can be used in order to secure a circuit board of the current sensor. The second connecting regions can be used in order to electrically connect the circuit board and/or the current sensor to external entities.

According to another implementation, further components, especially a circuit board of the current sensor and/or a second core part of the current sensor may be placed above the first core part in the molding tool before the step of injection-molding. The components may be embedded in the frame after the step of injection-molding. This allows to also injection-mold around these components, namely the circuit board and/or the second core part. This can form a compact structure with a material providing a surface under which the components of the current sensor and especially a portion of the current terminal may be arranged. These components may thus be protected.

The connecting pins may be fixed at the circuit board. They may protrude from the material of the frame after the step of injection-molding. This allows connection of an external entity. The connecting pins may be electrically connected with the circuit board inside the mold.

Especially, the connecting pins may each extend solely along a single line. This can especially mean that each connecting pin has a straight line and the cross section of the connecting pin is rotationally symmetric to this straight line, at least partly or in full.

All components arranged in the molding tool may be embedded in a block of the frame after the step of injection-molding. Afterwards, these components typically are covered by the material of the frame and are no longer visible.

Especially, the connecting pins may protrude outwards from the frame after injection-molding. These connecting pins are typically connected with the circuit board of the current sensor inside the mold. The connecting pins can be used in order to connect the circuit board electrically to external entities.

The current terminal may have one or more recesses for partially receiving the first core part and/or for positionally fixing the first core part. This can allow a secure and easy positioning of these components relative to each other.

The first core part and/or the second core part can have a U-shape and/or can together form a magnetic core of the current sensor.

A gap, or two gaps, may remain between the first core part and the second core part. This allows separate positioning and ideal control of a confined magnetic field.

The method may especially also comprise the following steps:
testing the current sensor, and
only if the testing the current sensor yields a positive result, making a mechanical and/or electrical connection between the current terminal or a frame and a semiconductor power switching circuit, thus fabricating a power module.

These steps can especially be performed after forming the frame and/or especially after the step of injection-molding. The current sensor can be calibrated and tested in a state in which it is not yet connected to a power switching circuit. Should the test yield a positive result, indicating that the current sensor is operating within previously defined limits, the current sensor can be connected appropriately. Should the test yield a negative result, meaning that the current sensor has a fault, the current sensor can be disposed of. Such a method avoids the production of a completed power module comprising a non-functional power sensor, and thus reduces waste and costs. With such a method, not only a frame, but also a working power module can be fabricated. For example, a cover may be secured to the frame in order to close a reception compartment of the frame. This can protect the semiconductor switching circuit. The cover may be releasably secured to the frame. This allows removing it, for example to do maintenance at the semiconductor switching circuit. The semiconductor switching circuit may especially comprise one or more switches, especially being embodied of semiconductor material, e.g. MOSFETs, IGBTs, or other transistors, that are able to switch and/or control a current flowing through the current terminal.

The invention further relates to a frame and a power module, being fabricated with a method as disclosed herein. With regard to the method, all disclosed variants can be applied.

In principle, one can differentiate two variants:

Variant 1 may be regarded as a partially integrated sensor:
The first core part core and sensor's pins may be solid molded within the frame, allowing full control of pin's tolerances
The second core part and the circuit board may be inserted and pressed after frame has been formed (especially by injection or transfer molding process), this solution requires double press-fit pins (or similar), as well as a circuit board with through-holes
The cavity can afterwards be filled-up with epoxy or similar ISO compound after the circuit board and the second core part have been placed

Variant 2 is the full integrated sensor:
The whole current sensor parts may be fixed and assembled within the molding jig
Injection or transfer molding process can be done in one or several steps according to the manufacturability, spacing and tools
This variant typically requires a simple single head press fit pins

For both variants, calibration and testing can be done on frame level prior to any semiconductor or substrate assembly: this is a great advantage of this solution since it mitigates the risk of yield loss in case of sensors malfunctioning prior to assembly.

Especially, the problem of integration of a current sensor as part of a power module may be solved by the means disclosed herein. Traditionally, current sensors are placed outside the housing of a completed power module. The means disclosed herein may provide for an all-in-one solution by embedding the current sensor directly into the power module space claim.

The concept may consist of embedding an open loop current sensor as part of the power module's housing. The sensor consisting of a traditional hall effect split core current sensor, it will be pre-mounted directly on the AC current terminal of the power module. The sensor will be encapsulated into the module's housing once the injection molding process is completed.

Possible benefits of the implementations disclosed herein:
Full Integration within module's space claim increasing power density.
Sensor can be assembled independently from the semiconductor assembly.
Cost effective solution.
Cross talk immunity.
Straightforward sensor assembly.
Simple connection to driver board.
Solving Creepage constraints on PCB.
Potential for full vibration proof solution.

### BRIEF DESCRIPTION OF THE DRAWINGS

The invention will now be described with reference to the drawings, wherein:

FIG. 1: shows parts of a power module according to a first embodiment,

FIG. 2: shows a power module according to the first embodiment,

FIG. 3: shows a connecting pin,

FIG. 4: shows a circuit board,

FIG. 5: shows parts of a power module according to a second embodiment,

FIG. 6: shows a power module according to the second embodiment,

FIG. 7: shows a further connecting pin.

FIG. 8: shows a power module,

FIG. 9: shows a further power module,

FIG. 10: shows a molding tool with components,

FIG. 11: shows the molding tool with components in another state, and

FIG. 12: shows components of the frame.

### DETAILED DESCRIPTION

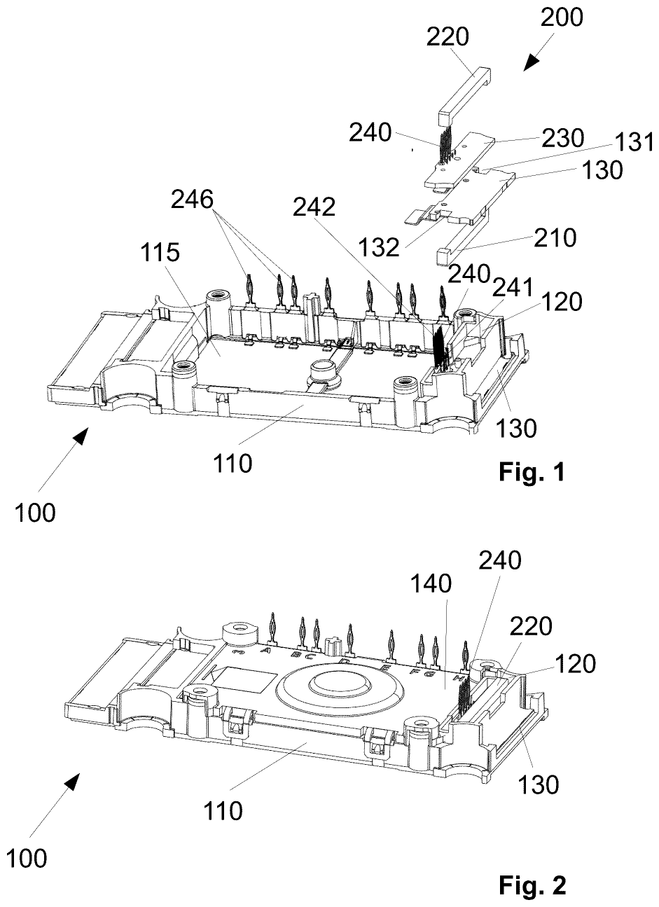

FIG. 1 shows parts of a power module 100 according to a first embodiment. Especially, there is shown a frame 110, which forms a basis for securing further components to it of which the power module 100 is to be made.

The frame 110 comprises a cavity 120 which is opened to the upper side. In this cavity 120, components of a current sensor 200 are to be placed, which are also shown separately in FIG. 1. These components comprise a first core part 210, a second core part 220, and a circuit board 230. In final state, the first core part 210 and the second core part 220 form a magnetic core together, in order to confine a magnetic field that is to be measured by magnetic sensors or a magnetic sensor, e.g. a Hall sensor, especially being connected to the circuit board 230.

Furthermore, a current terminal 130 is to be placed at the frame 110 in order to allow a current to flow to or from a semiconductor power switching circuit which is not shown in FIG. 1. The current terminal 130 comprises a first recess 131 and a second recess 132 which confine the first core part 210 so that the positional relationship between the first core part 210 and the current terminal 130 is to be defined.

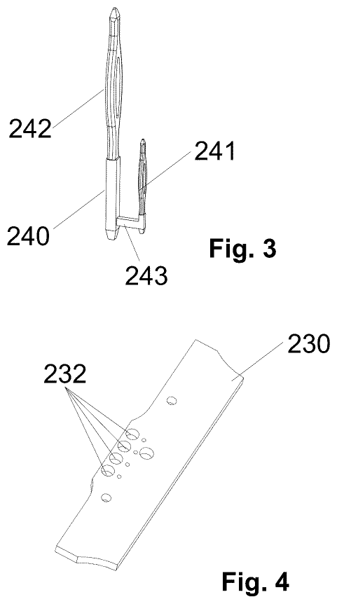

Furthermore, FIG. 1 shows a plurality of connecting pins 240, which will be shown in more detail in FIG. 3. These connecting pins 240 serve to connect the circuit board 230 with external components. They may be regarded part of the current sensor 200.

The components of the current sensor 200 are shown separately to the frame 110 in FIG. 1, but are also partly already incorporated in the frame 110 shown in FIG. 1. The separate view is for illustration. The current terminal 130 is also incorporated in the frame 110. The first core part 210 is arranged inside the frame 110 under the current terminal 130 and is embedded in material of the frame 110 formed by injection-molding. The connecting pins 240 are also shown in FIG. 1, wherein first connecting regions 241 of the connecting pins 240 and second connecting regions 242 of the connecting pins 240 protrude from the material of the frame 110. Thus, the circuit board 230 of the current sensor can be secured to the first connecting regions 241. This holds the circuit board 230 in place and the second connecting regions 242 can be used in order to electrically connect the circuit board 230 to external components.

In FIG. 1, there are also shown further connecting parts 246 which are also attached at the frame 110. These further connecting parts 246 can, as the first core part 210 and current terminal 130, be partially placed in a molding tool that is used in order to produce the frame 110.

The frame 110 comprises a reception compartment 115 that will be used in order to receive a semiconductor switching component as shown further below. In the state shown in FIG. 1, the reception compartment 115 is open both to the upper side and to the lower side.

FIG. 2 shows a state after steps of placing the components shown in FIG. 1 in their correct final position. The second core part 220 is visible in FIG. 2, being arranged above the circuit board 239 in the cavity 120. The frame 110, especially its reception compartment 115, is covered by a cover 140, which is releasably secured to the frame 110. The cover 140 covers a region in which a semiconductor switching circuit is to be placed, as will be shown further below. Such a cover 140 thus forms a final outer surface of the power module 100 and may also cover a semiconductor switching component, or semiconductor power switching circuit, switching a current flowing through the current terminal 130.

The cavity 120 is still open to the upper side in the state shown in FIG. 2. The cavity 120 may then be filled with a material, especially a non-conducting material for final protection and containment.

FIG. 3 shows a connecting pin 240 that is used in order to connect the circuit board 230, being shown in FIG. 4, to outside components. According to the first embodiment shown in FIGS. 1 to 3, the connecting pin 240 has a first connecting region 241 and a second connecting region 242, which form a U-shape of the connecting pin 240 together with a base portion 243, which may also be called a connecting portion or a bottom portion. As shown in FIG. 3, the two connecting regions 241, 242 each extend straight and parallel to each other. The first connecting region 241 is shorter compared with the second connecting region 242. The first connecting region 241 is connected with one of a plurality of corresponding holes 232 formed in the circuit board 230. The second connecting regions 242 extend out of the upper side of the frame 110 and serve to connect the circuit board 230 with external components.

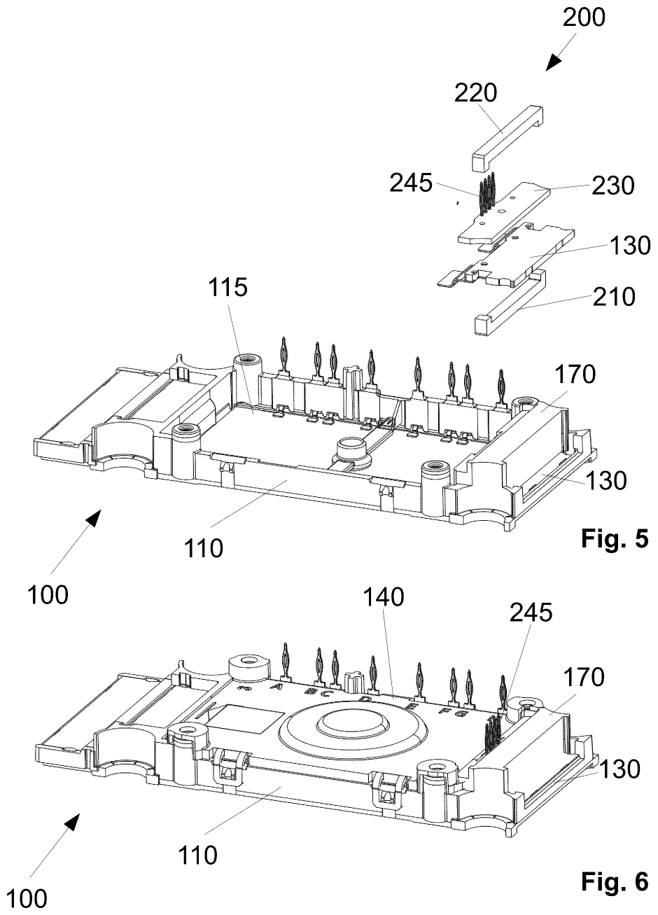

The FIGS. 5 to 7 correspond in principle to FIGS. 1 to 3, but show a second embodiment of a power module 100 and its components.

In contrast to the first embodiment, the components of the current sensor 200, which are separately shown in FIG. 5 for illustrative purposes, are completely covered by a material of the frame 110 formed as block 170. FIG. 5 shows an open state with the reception compartment 115 being open, while FIG. 6 shows a state in which a cover 140 covers the frame 110.

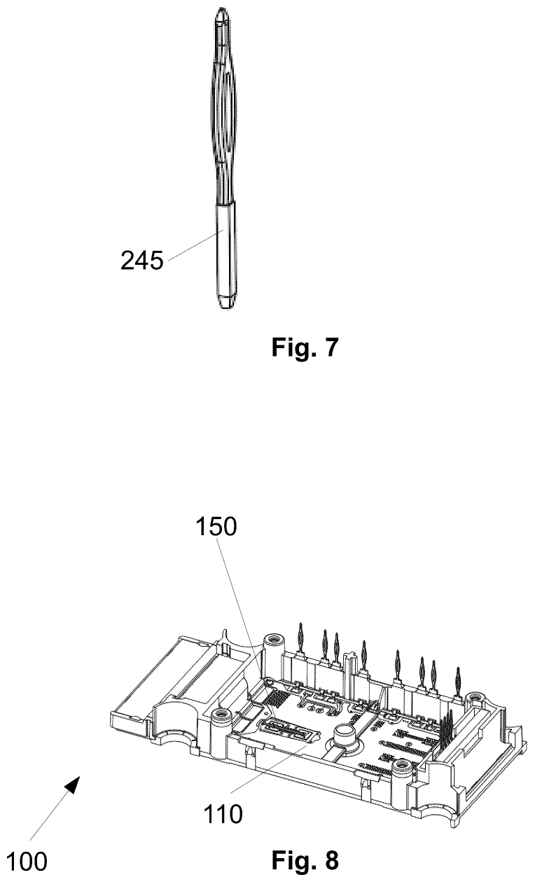

Thus, an alternative shape of connecting pins 245 can be used, as is shown in detail in FIG. 7. The connecting pins 245 extend along a straight line and only contact the circuit board 230 from above, not from below as in the first embodiment.

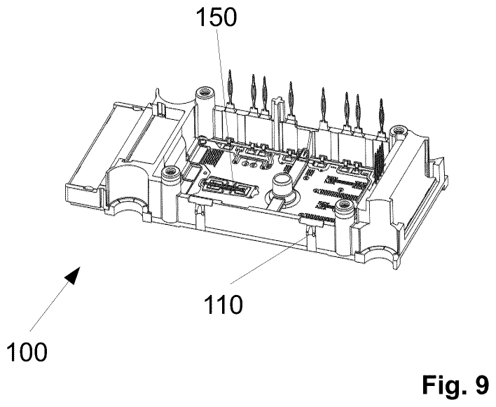

FIG. 8 shows a power module 100 with a frame 110 with a semiconductor switching circuit 150 being placed inside it. This semiconductor switching circuit 150 can be arranged inside the frame 110 especially after a test of the current sensor 200 has been performed and has yielded a positive result. While FIG. 8 shows an implementation in which the second core part and the circuit board of the current sensor are not injection-molded in the first step (corresponding to the first embodiment), FIG. 9 shows a corresponding implementation in which these components of the current sensor are also injection-molded in the first step (corresponding to the second embodiment).

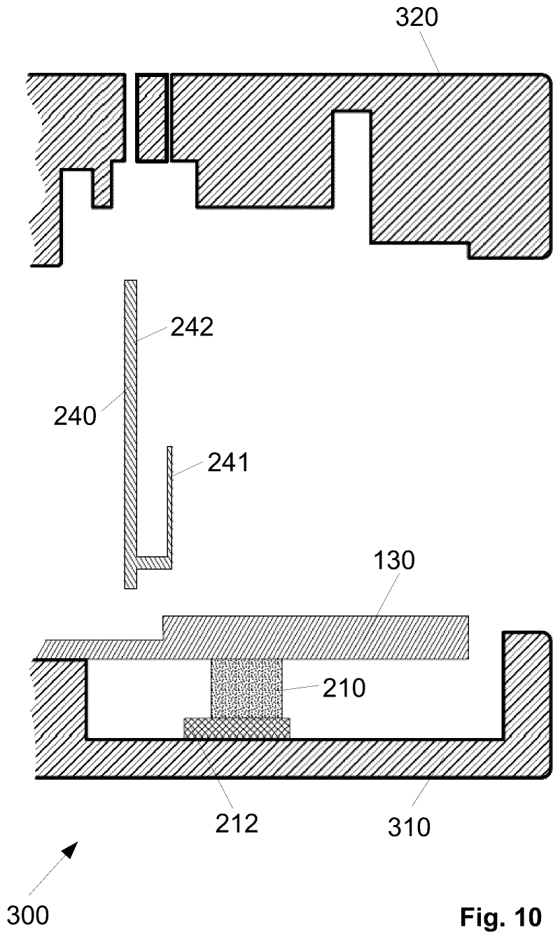

FIG. 10 shows a molding tool 300 comprising a first part 310 being a lower part and a second part 320 being an upper part. Between these parts 310, 320 a mold process is to be performed. For that purpose, the first core part 210 with a distance element 212 between the first part 310 and the first core part 210, the current terminal 130, and the connecting pins 240 are placed into the molding tool 300. For convenience, only one connecting pin 240 is shown in FIG. 10. In an alternative implementation of the method, also the second core part 220 and the circuit board 230 of the current sensor 200 may be placed inside the molding tool 300.

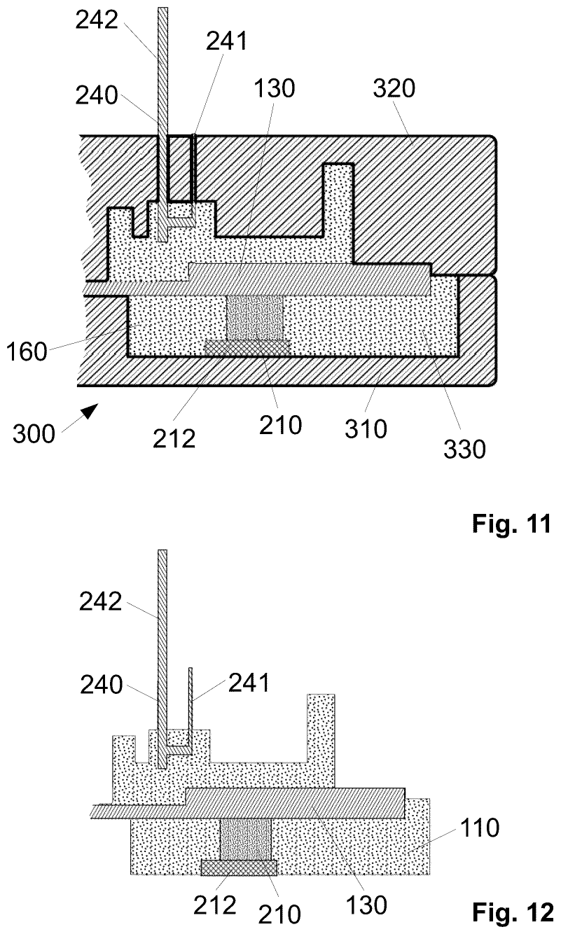

After bringing the parts 310, 320 of the molding tool 300 together, they form a hollow space 330, in which a mold material 160 is to be filled. This is shown in FIG. 11. After hardening of the mold material 160, the molding tool 300 can be removed, leaving the components as shown in FIG. 12 with a material of the frame 110 being formed out of the hardened mold material 160. Especially, the connecting pin 240 is secured in the material of the frame 110 so that its position remains fixed. The circuit board 230 can then be placed on top of the components shown in FIG. 12 and can especially be fixed to the respective first connecting regions 241 of the connecting pins 240. This also holds the circuit board 230 in position.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A method for fabricating a frame of a power module, the method comprising the following steps:
providing a molding tool,
arranging components, namely at least a portion of a current terminal, at least a first core part of a core of a current sensor, and a portion of one or more connecting pins of the current sensor in the molding tool, and
forming the frame using the molding tool by injection-molding around the components arranged in the molding tool so that the components are embedded in the frame.

2. The method according to claim 1,
wherein the frame is formed to comprise a reception compartment for a semiconductor switching circuit.

3. The method according to claim 2,
wherein the molding tool comprises a first part and a second part being detachably fixed to each other and defining a hollow space between them in which a mold material is to be entered for injection-molding.

4. The method according to claim 1, further comprising, after the step of injection-molding, the following step:
placing a circuit board of the current sensor and a second core part of the current sensor above the first core part outside a material forming the frame.

5. The method according to claim 4,
wherein the connecting pins are double-headed pins each having a first connecting region facing upwards and a second connecting region facing upwards.

6. The method according to claim 5,
wherein the circuit board of the current sensor is fixed on the first connecting regions.

7. The method according to claim 4,
wherein the frame is formed with a cavity in which the circuit board and the second core part are to be placed.

8. The method according to claim 7,
wherein one or more connecting regions of the connecting pins extend into the cavity after forming the frame.

9. The method according to claim 8,
wherein the cavity is filled with a non-conducting material, or an epoxy material, after the step of placing a circuit board of the current sensor and a second core part of the current sensor above the first core part.

10. The method according to claim 5,
wherein the connecting pins have a U-shape.

11. The method according to claim 5,
wherein the first connecting regions and/or the second connecting regions protrude outwards from the frame after injection-molding.

12. The method according to claim 1,
wherein further components, namely a circuit board of the current sensor and a second core part of the current sensor are placed above the first core part in the molding tool before the step of injection-molding and are embedded in the frame after the step of injection-molding.

13. The method according to claim 12,
wherein the connecting pins are fixed at the circuit board.

14. The method according to claim 12,
wherein the connecting pins each extend solely along a single line.

15. The method according to claim 12,
wherein all components arranged in the molding tool are embedded in a block of the frame after the step of injection-molding.

16. The method according to claim 12,
wherein the connecting pins protrude outwards from the frame after injection-molding.

17. The method according to claim 1,
wherein the current terminal has one or more recesses for partially receiving the first core part and/or for positionally fixing the first core part.

18. The method according to claim 1,
wherein the first core part and/or the second core part has/have a U-shape and/or together form a magnetic core of the current sensor.

19. The method according to claim 1,
wherein a gap, or two gaps, remain between the first core part and the second core part.

20. The method according to claim 1, further comprising the following steps:
testing the current sensor, and
only if the testing the current sensor yields a positive result, making a mechanical and/or electrical connection between the current terminal and/or a frame and a semiconductor power switching circuit, thus fabricating a power module.

21. A frame of a power module, being fabricated with a method comprising the following steps:
providing a molding tool,
arranging components, namely at least a portion of a current terminal, at least a first core part of a core of a current sensor, and a portion of one or more connecting pins of the current sensor in the molding tool, and
forming the frame using the molding tool by injection-molding around the components arranged in the molding tool so that the components are embedded in the frame,
or power module, being fabricated according to claim 20.
